(19) United States
(12) Patent Application Publication
(10) Pub. No.: US 2010/0050932 A1
(43) Pub. Date: Mar. 4, 2010

(54) Apparatus and Method of Direct Electric Melting a Feedstock

(75) Inventors: Nathan G. Stoddard, Gettysburg, PA (US); Paul Von Dollen, Frederick, MD (US)

Correspondence Address: CAROL WILSON;BP AMERICA INC., MAIL CODE 5 EAST, 4101 WINFIELD ROAD, WARRENVILLE, IL, 60555, US

(73) Assignee: BP Corporation North America Inc., Warrenville, IL (US)

(21) Appl. No.: 12/548,015

(22) Filed: Aug. 26, 2009

Related U.S. Application Data
(60) Provisional application No. 61/114,091, filed on Nov. 13, 2008.
(60) Provisional application No. 61/092,186, filed on Aug. 27, 2008.

(51) Int. Cl. C30B 9/00

(52) U.S. Cl. 117/73; 117/206

(57) ABSTRACT

This invention relates to an apparatus and a method of direct electric melting a feedstock, such as high purity silicon for use in solar cells or solar modules. The continuous melting apparatus includes a first electrode opposite a second electrode and forming a melting zone. The electric current passes from the first electrode through a feedstock and enters the second electrode. The apparatus also includes an opening for draining a molten feedstock from the melting zones and a catch pan for receiving the molten feedstock from the opening.

This application claims the benefit of U.S. Provisional Application No. 61/114,091, filed Nov. 13, 2008 and U.S. Provisional Application No. 61/092,186 filed Aug. 27, 2008, the entirety of both are expressly incorporated herein by reference.

This invention was made with U.S. Government support under Cooperative Agreement No.: DE-FC36-07G017049 under prime contract with the National Renewable Energy Laboratory awarded by the Department of Energy. The Government has certain rights in this invention.

### BACKGROUND

1. Technical Field

This invention relates to an apparatus and a method of direct electric melting a feedstock, such as high purity silicon for use in solar cells or solar modules.

2. Discussion of Related Art

Photovoltaic cells convert light into electric current. One of the most important features of a photovoltaic cell is its efficiency in converting light energy into electrical energy. Although photovoltaic cells can be fabricated from a variety of semiconductor materials, silicon is generally used because it is readily available at reasonable cost, and because it has a suitable balance of electrical, physical, and chemical properties for use in fabricating photovoltaic cells.

In a known procedure for the manufacture of photovoltaic cells, silicon feedstock is doped with a dopant having either a positive or negative conductivity type, melted, and then crystallized by pulling crystallized silicon out of a melt zone into ingots of monocrystalline silicon (via the Czochralski (CZ) or float zone (FZ) methods). For a FZ process, solid material is fed through a melting zone, melted upon entry into one side of the melting zone, and re-solidified on the other side of the melting zone, generally by contacting a seed crystal.

Recently, a new technique for producing monocrystalline or geometric multicrystalline material in a crucible solidification process (i.e. a cast-in-place or casting process) has been invented, as disclosed in U.S. patent application Ser. Nos. 11/624,365 and 11/624,411, and published in U.S. Patent Application Publication Nos. 20070169684A1 and 20070169685A1, filed Jan. 18, 2007. Casting processes for preparing multicrystalline silicon ingots are known in the art of photovoltaic technology. Briefly, in such processes, molten silicon is contained in a crucible, such as a quartz crucible, and is cooled in a controlled manner to permit the crystallization of the silicon contained therein. The block of cast crystalline silicon that results is generally cut into bricks having a cross-section that is the same as or close to the size of the wafer to be used for manufacturing a photovoltaic cell, and the bricks are sawn or otherwise cut into such wafers. Multicrystalline silicon produced in such manner is composed of crystal grains where, within the wafers made therefrom, the orientation of the grains relative to one another is effectively random. Monocrystalline or geometric multicrystalline silicon has specifically chosen grain orientations and (in the latter case) grain boundaries, and can be formed by the new casting techniques disclosed in the above-mentioned patent applications by melting in a crucible the solid silicon into liquid silicon in contact with a large seed layer that remains partially solid during the process and through which heat is extracted during solidification, all while remaining in the same crucible. As used herein, the term ‘seed layer’ refers to a crystal or group of crystals with desired crystal orientations that form a continuous layer. They can be made to conform to one side of a crucible for casting purposes.

In order to produce high quality cast ingots, several conditions should be met. Firstly, as much of the ingot as possible should have the desired crystallinity. If the ingot is intended to be monocrystalline, then the entire usable portion of the ingot should be monocrystalline, and likewise for geometric multicrystalline material. Secondly, the silicon should contain as few imperfections as possible. Imperfections can include individual impurities, agglomerates of impurities, intrinsic lattice defects and structural defects in the silicon lattice, such as dislocations and stacking faults. Many of these imperfections can cause a fast recombination of electrical charge carriers in a functioning photovoltaic cell made from crystalline silicon. This can cause a decrease in the efficiency of the cell.

Many years of development have resulted in a minimal amount of imperfections in well-grown CZ and FZ silicon. Dislocation free single crystals can be achieved by first growing a thin neck where all dislocations incorporated at the seed are allowed to grow out. The incorporation of inclusions and secondary phases (for example silicon nitride, silicon oxide or silicon carbide particles) is avoided by maintaining a counter-rotation of the seed crystal relative to the melt. Oxygen incorporation can be lessened using magnetic CZ techniques and minimized using FZ techniques as is known in the industry. Metallic impurities are generally minimized by being segregated to the tang end or left in the potscrap after the boule is brought to an end.

However, even with the above improvements in the CZ and FZ processes, there is a need and a desire to produce high purity crystalline silicon that is less expensive on a per volume basis, needs less capital investment in facilities, needs less space, and/or less complexity to operate, than known CZ and FZ processes. There is a desire and a need for a more efficient melting apparatus and method using Joule heating. There is also a desire and a need for a continuous melting process that maintains the high purity of the feedstock. There is also a desire and a need for a continuous melting process that can handle random size chunks of feedstock.

### SUMMARY

This invention relates to an apparatus and a method of direct electric melting a feedstock, such as high purity silicon for use in solar cells or solar modules. This invention includes a more efficient melting apparatus and method using Joule heating. This invention also includes a melter and a continuous melting process that maintains the high purity of the feedstock. This invention also includes a process that handles or accommodates random size chunks of silicon.

According to a first embodiment, this invention includes a continuous melting apparatus suitable for producing high purity silicon. The apparatus includes a first electrode opposite a second electrode and forming a melting zone. The electric current passes from the first electrode through a feedstock and enters the second electrode. The apparatus also includes an opening for draining a molten feedstock from the melting zone, and optionally a catch pan or a crucible for receiving the molten feedstock from the opening.

According to a second embodiment, this invention includes a method of continuously melting a feedstock suitable for high purity silicon. The method includes the step of providing a solid feedstock, and the step of supplying the solid feedstock into a melting zone between a first electrode and a second electrode. The method also includes the step of passing an electric current from the first electrode through the solid feedstock to the second electrode to melt the solid feedstock into a molten feedstock, and the step of flowing the molten feedstock through an opening between the first electrode and the second electrode optionally into a catch pan or a crucible for receiving the molten feedstock.

According to a third embodiment, this invention includes a high purity silicon ingot suitable for use in solar cells and solar modules.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention. In the drawings:

FIG. 1 illustrates a partial side sectional view of a melting apparatus, according to one embodiment;

FIG. 2 illustrates an isometric view of a melting apparatus, according to one embodiment;

FIG. 3A illustrates a top view of an insulating material, according to one embodiment;

FIG. 3B illustrates a top view of a silicon plug, according to one embodiment; and

FIG. 4 illustrates a partial side sectional view of a feed assembly, according to one embodiment.

### DETAILED DESCRIPTION

This invention relates to an apparatus and a method of direct electric melting a feedstock, such as high purity silicon for use in solar cells or solar modules. A known silicon melting technique for high purity applications, such as electronic or solar wafer production, involves resistive heating. Conventional resistive heating employs a resistive heater and a radiative transfer, sometimes referred to as “indirect resistive” heating or “induced radiative” heating. Another known heating technique is inductive heating.

Resistive heating is accomplished by passing current through an element composed of a material, such as graphite, which is heated and undergoes black body radiation to transfer heat to material within the line of sight of the heater element. Resistive heating applies energy to the heater element, which becomes the hottest part of the furnace with efficiencies on the order of about 70 percent. Since the energy is applied remotely and transferred by radiation, the purity of the silicon is limited only by the containing crucible and/or impurities in the feedstock.

Inductive heating includes two techniques. One technique involves direct coupling of the material to be melted with an electromagnetic (EM) field generated by a series of coils, such as water-cooled copper tubing. The second technique involves indirect coupling of copper coils to a conductive susceptor or intermediary, such as graphite, which subsequently radiates heat to the material to be melted. In the first technique, high temperature gradients between the water cooled conductor and the material being melted typically limit the efficiency of this method to less than about 10 percent. Additionally, the close proximity of feedstock and copper can cause unwanted contamination of the finished product. In the second technique, the efficiency can be better than in the first technique, but since the mechanism of heat transfer between the susceptor and charge of feedstock is through radiation, this method is still no better than traditional resistive heating.

Additionally, both of these general heating methods (resistive and inductive) include complications of geometry and material introduction when integrated in a high-purity continuous loading and melting process. Known methods for continuous introduction of silicon to a melting furnace have typically been constrained to feedstock that has been crushed to small chips or particles in order to control material introduction rates and to protect the brittle, high purity silica crucible used to contain feedstock.

According to one embodiment, this invention applies electrical energy directly to the feedstock to be melted allowing easy integration into a continuous melting system while maintaining high melting efficiencies in a simple melter and material supply device. Desirably, the process of this invention allows silicon chunks of arbitrary size to be loaded and melted while maintaining high purity. The apparatus and method of this invention can be implemented for any application requiring continuous feeding and melting of a resistive feedstock, such as metals, ores, refractories, ceramics, and/or the like. The melter of this invention desirably has a small or compact foot print while having a high power output or density.

According to one embodiment, this invention includes two plates of an electrically conductive material, such as graphite or silicon carbide, separated by a gap or by insulating material, such as silicon dioxide or silica. The two plates can be connected to an electrical circuit such that the plates have opposite polarities or charges. The plates may be arranged at an angle to one another forming a V-shape when viewed from the side. The open ends of the V-shape can be enclosed with electrically insulating materials. In the alternative, electrically active elements could be mounted almost entirely within an electrically insulating block, such as with just one face of each exposed.

Feedstock or material to be melted can be introduced at the top of the plates in a continuous manner, a semi-continuous manner, a batch manner, a semi-batch manner, and/or the like. A conveyor-type system, a chute, a rotary feeder, a load lock, and/or any other suitable mechanism or configuration can deliver the feedstock to the plates.

The feedstock may or may not be pre-heated to near its melting temperature. An electrical circuit can be completed when some of the material to be melted forms a continuous solid network bridging the gap between the two plates, such as a current passes between the plates through the solid network of the material to be melted. The completed electrical circuit may result in Joule heating (increasing the internal temperature or enthalpy) of the material, eventually heating it to its melting point.

Upon melting, liquid can percolate or drip by gravity through the still bridging solid network and exit the melter through the gap between the plates. As the solid melts the feedstock moves towards the bottom of the plates due to the angled nature of the plates and maintains a solid bridge for electrical current. Therefore, the current between the plates can be maintained, resulting in continuous melting.

Additional material may be added throughout the process simply by depositing additional solid material on top of the charge of feedstock, such as by dropping, placing, loading, conveying, and/or the like. Generally, fused silica can be in prolonged contact with molten silicon in high purity applications. According to one embodiment, this invention includes the use of high purity graphite or silicon carbide for the short times or durations of contact with the molten silicon. Desirably, the geometry of the apparatus provides that most of the material would be in contact only with other silicon, while the melted material drops immediately into a silica tray, avoiding excessive carbon incorporation or entrainment of impurities.

Initiation of melting can be done using several methods, such as by careful hand-loading of silicon into the V-shaped plates, by charging chips to disperse the impact force of subsequent heavier chunks, and/or by introducing a shaped cast silicon plug to seal or block the bottom gap between the plates. Recharging of feedstock can be accomplished by dropping a variety of feedstock chunks onto feedstock already in the melter. The silicon in the melter may cushion the impact of the additional material. Melting can be easily started and stopped through control of the applied current. Additionally, there can be pre-heating of the feedstock. Resistive preheating can be efficient at room temperature, particularly since the solid material does not directly fall into a hot liquid (radiation source). The methods of this invention include increased efficiency based on direct energy incorporation, such as by convection, conduction and/or radiation.

According to one embodiment, this invention includes continuous melting of material through the application of electric current between separated conductive plates and through material contained between the plates. The material between the plates can be heated and melted through Joule heating. The process can be continuous since the plates are angled, allowing a continuous conductive bridge to be maintained while liquid constantly percolates or drips through the bottom gap in the plates. New material may be introduced at the top of the plates and piled on top of already present material. A high purity of the material can be maintained during the melting process. This invention encompasses the concepts of using direct application of Joule heating to melt material efficiently and maintain high purity, such as with the use of an angled geometry to allow continuous melting, removal of liquid, and introduction of new solid material.

The term “Joule heating” broadly includes the process of passing an electric current through a conductor to release heat. Without being bound by theory of operation, joule heating can be caused by interactions between the moving particles that form the current (usually, but not always, electrons) and the atomic ions that make up the body of the conductor. Charged particles in an electric circuit can be accelerated by an electric field but give up some of their kinetic energy each time they collide with an ion. The increase in the kinetic or vibrational energy of the ions manifests itself as heat and a rise in the temperature of the conductor. Hence energy can be transferred from the electrical power supply to the conductor and any materials with which it is in thermal contact.

The solid feedstock may include silicon and/or any other suitable material. The solid feedstock may include any suitable size and/or shape. Desirably, but not necessarily, the solid feedstock includes an average particle size of at least 2 centimeters to about 30 centimeters, such as about 5 centimeters. The solid feedstock may be random, pelletized, crushed to size, classified and/or otherwise sized or sorted. The solid feedstock may include a powder or, in the alternative, exclude a powder.

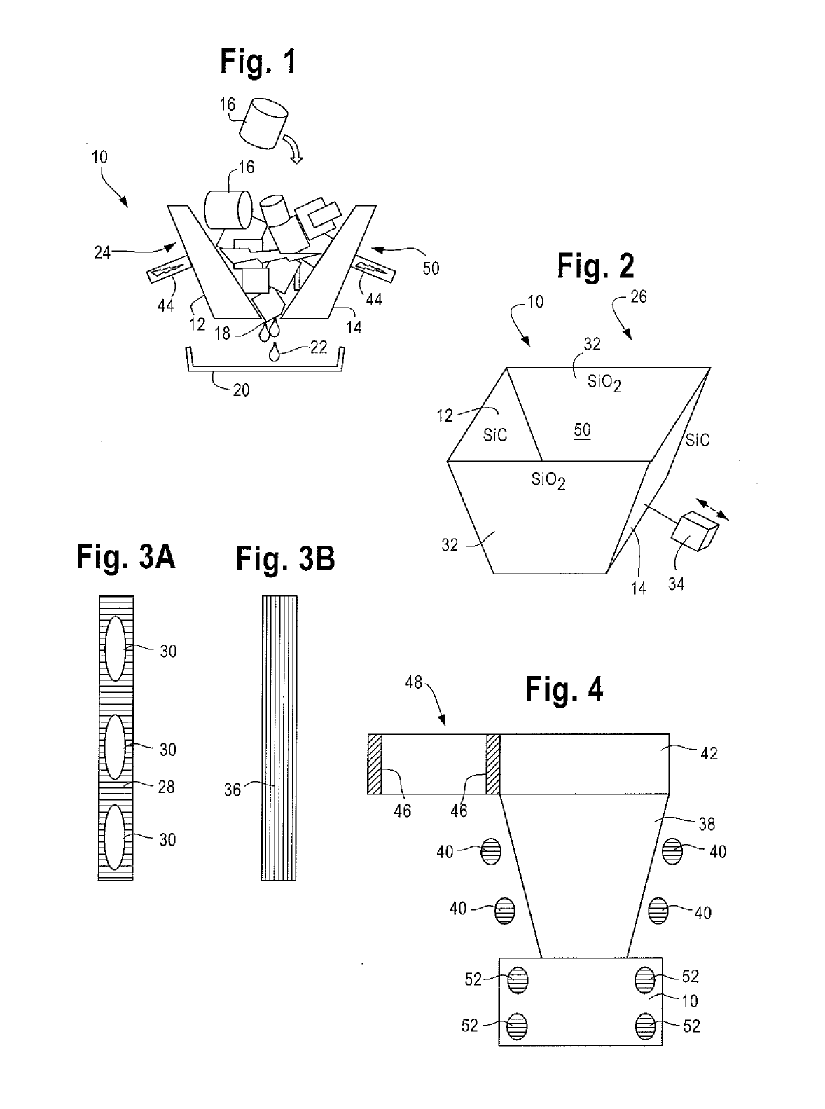

FIG. 1 shows a partial side sectional view of a continuous melting apparatus 10, according to one embodiment. The melting apparatus 10 includes a first electrode 12, such as a negative electrode wall, a second electrode 14, such as a positive electrode wall, an opening 18, and a catch pan 20 or a crucible (not shown). The electrodes 12 and 14 include a V-shaped cross section 24 and form a melting zone 50. Electricity flowing through electrical connections 44 power or energize the melting apparatus 10. Chunks or pieces of solid feedstock 16 bridge from the first electrode 12 to the second electrode 14 to complete a circuit and initiate Joule heating. The Joule heating melts the solid feedstock 16 into molten feedstock 22 so that it flows out of the melting zone 50 through the opening 18. Electricity may flow through solid feedstock 16 and/or molten feedstock 22.

FIG. 2 shows an isometric view of a melting apparatus 10, according to one embodiment. The ends of the first electrode 12 and the second electrode 15 can be enclosed or covered with insulating walls 32, such as to form a trapezoidal shape 26 and a melting zone 50. A motive force device 34 may reciprocate or move at least a portion of the second electrode 14, such as with an in-and-out motion.

FIG. 3A shows a top view of an insulating material 28, according to one embodiment. The insulating material 28 includes apertures 30, such as to allow molten feedstock (not shown) to flow. The insulating material 30 can be placed in the opening 18 (not shown), such as to catch pieces of unmelted feedstock.

FIG. 3B shows a top view of a silicon plug 36, according to one embodiment. The silicon plug 36 can be placed in the opening 18 (not shown), such as during startup.

FIG. 4 shows a partial side sectional view of a feed assembly 48 positioned with respect to the melting apparatus 10, according to one embodiment. The feed assembly 48 delivers solid feedstock 16 (not shown) to the melting apparatus 10, such as surrounded or shrouded by insulation. The feed assembly 48 includes a chute 38, additional heaters 40, and a load lock 42 with doors 46. The load lock 42 to may include any suitable conveying device (not shown), such as to move through or advance the feedstock with respect to the doors 46. The solid feedstock 16 (not shown) can be advanced though the load lock 42 by opening and closing the doors 46 while providing an inert atmosphere. The solid feedstock 16 (not shown) can flow down the chute 38 and into the melting zone 50 (not shown). The supplemental heaters 52 may be disposed within the melting apparatus 10 and with respect to the melting zone 50 (not shown).

Moreover, although casting of silicon has been described herein, other semiconductor materials and nonmetallic crystalline materials may be cast without departing from the scope and spirit of the invention. For example, the inventors have contemplated casting of other materials consistent with embodiments of the invention, such as germanium, gallium arsenide, silicon germanium, aluminum oxide (including its single crystal form of sapphire), gallium nitride, zinc oxide, zinc sulfide, gallium indium arsenide, indium antimonide, germanium, yttrium barium oxides, lanthanide oxides, magnesium oxide, calcium oxide, and other semiconductors, oxides, and intermetallics with a liquid phase. In addition, a number of other group III-V or group II-VI materials, as well as metals and alloys, could be cast according to embodiments of the present invention.

Cast silicon includes multicrystalline silicon, near multicrystalline silicon, geometric multicrystalline silicon, and/or monocrystalline silicon. Multicrystalline silicon refers to crystalline silicon having about a centimeter scale grain size distribution, with multiple randomly oriented crystals located within a body of multicrystalline silicon.

Geometric multicrystalline silicon or geometrically ordered multicrystalline silicon refers to crystalline silicon having a nonrandom ordered centimeter scale grain size distribution, with multiple ordered crystals located within a body of multicrystalline silicon. The geometric multicrystalline may include grains typically having an average about 0.5 centimeters to about 5 centimeters in size and a grain orientation within a body of geometric multicrystalline silicon can be controlled according to predetermined orientations, such as using a combination of suitable seed crystals.

Polycrystalline silicon refers to crystalline silicon with micrometer to millimeter scale grain size and multiple grain orientations located within a given body of crystalline silicon. Polycrystalline silicon may include grains typically having an average of about submicron to about micron in size (e.g., individual grains are not visible to the naked eye) and a grain orientation distributed randomly throughout.

Monocrystalline silicon refers to crystalline silicon with very few grain boundaries since the material has generally and/or substantially the same crystal orientation. Monocrystalline material may be formed with one or more seed crystals, such as a piece of crystalline material brought in contact with liquid silicon during solidification to set the crystal growth. Near monocrystalline silicon refers to generally crystalline silicon with more grain boundaries than monocrystalline silicon but generally substantially fewer than multicrystalline silicon.

Silicon of the above described types and kinds may be cast and/or formed into blocks, ingots, bricks, wafers, any suitable shape or size, and/or the like. The silicon may include a positive or negative dopant, such as altering the electrical properties of the silicon.

The high purity silicon made with this invention may include any suitable level of reduced impurities. Impurities broadly include carbon, silicon carbide, silicon nitride, oxygen, other metals, and/or substances which generally reduce an efficiency of a solar cell or a solar module. The ingot may include a carbon concentration of about 2×10¹⁶ atoms/centimeter cubed to about 5×10¹⁷ atoms/centimeter cubed, an oxygen concentration not exceeding 7×10¹⁷ atoms/centimeter cubed, and a nitrogen concentration of at least 1×10¹⁵ atoms/centimeter cubed. Desirably, the ingot may further be substantially free from radially distributed defects, such as made without the use of rotational (spinning) processes and/or pulling.

According to one embodiment, this invention may include a continuous melting apparatus suitable for producing high purity silicon. The apparatus may include a first electrode opposite a second electrode and forming a melting zone. An electric current can pass from the first electrode through a feedstock and enter the second electrode in the melting zone. The apparatus may also include an opening for draining a molten feedstock from the melting zone, and optionally a catch pan or a crucible for receiving the molten feedstock from the opening.

The term “continuous” refers broadly to substantially without interruption.

The term “melting” refers broadly to increasing an internal energy (enthalpy) of a substance to the melting point and causing a phase change, such as from a solid to a liquid. Liquids generally have a fixed volume but not a fixed shape. Melting may include increasing the temperature of the substance to the melting point, such as providing sensible heat. Silicon has a specific heat capacity of about 19.789 J·mol⁻¹·K⁻¹. Melting may also include supplying the heat of fusion needed for the phase change. Silicon has a heat of fusion of about 50.21 kJ*mol⁻¹ to go from solid to liquid. Silicon has a melting point of about 1420 degrees Celsius.

The term “electrode” broadly refers to device or structure used to establish electrical contact with the feedstock. Desirably, the electrode includes sufficient electrical properties while maintaining a purity of the feedstock and/or finished product. The electrodes may have any suitable size and/or shape. The electrodes may be generally triangular, generally square, generally rectangular, and/or the like. A length or width of the electrodes may range from about 10 centimeters to about 150 centimeters, about 50 centimeters to about 100 centimeters, and/or the like. The electrode may have a thickness that varies with a height, such as increased thickness on a bottom and a reduced thickness on the top. In the alternative, the thickness of the electrode remains generally constant with respect to height.

The electrode may be made from any suitable material, such as graphite, high purity graphite, silicon carbide, coated carbon-carbon composite material (C-C), other high-temperature conductive material compatible with the special purity requirements of molten silicon processes for photovoltaic applications, and/or the like. The coatings for the carbon-carbon composite or carbon fiber composite material may include any suitable material with sufficient electrical conductivity, mechanical integrity, and/or chemical inertness to the molten silicon and the surrounding atmosphere.

The coatings may include silicon carbide (SiC), such as deposited through either solid or gas phase reactions. Deposition may include pack cementation or slurry sintering for the first and chemical vapor deposition and/or chemical vapor infiltration for the second, for example. Another coating may include a diamond or diamond-like form of carbon. In the alternative, the coating may include conductive ceramics, such as from the perovskite family and including SrTiO₃, LaMnO₃, LaCoO₃, and/or the like. Another coating may include silicon nitride (Si₃N₄), such as doped to be conductive.

Desirably, the electrode includes a connection, an interface, a bus, a plug, and/or the like, such as for electrically connecting the electrode to a current source, a power supply, a ground reference, and/or the like.

The term “opposite” broadly refers to being set over against something that is at the other end or side of an intervening line or space. Opposite may include being situated in pairs on an axis with each member being separated from the other by half the circumference of the axis, for example.

The term “melting zone” broadly refers to a space or a region bounded at least in part by the first electrode and the second electrode, such as where the melting occurs. The melting zone may include where the electrical current passes through at least a portion of the feedstock and at least a portion of the feedstock changes from a solid state into a liquid state. The melting zone may include any suitable size (length, width, and depth) and/or shape, such as a volume of between about 0.01 meters cubed and about 1.0 meters cubed, between about 0.05 meters cubed and about 0.5 meters cubed, about 0.2 meters cubed, and/or the like.

The term “electrical current” broadly refers to the flow or movement of an electric charge, such as electrons or ions. Electrical current may be measured in amperes or amps. As discussed above current passing or flowing through an object can result in Joule heating. Depending upon the amount of current, the voltage, and/or the internal electrical resistance of the object, the level of heating can be increased or decreased. Desirably, the electrical current completes a circuit, such as flowing between the polarities of the first electrode and the second electrode.

The opening or aperture provides a drain or an exit for the molten feedstock to flow from the melting zone, such as at or on a bottom. The flowing of molten feedstock may include gravity-based flow and/or may include mechanical assistance to rake (with a mechanical mechanism) or urge molten feedstock into the opening. The opening may include any suitable size and/or shape, such as a generally square shape, a generally rectangular shape, and/or the like. According to one embodiment, the opening has the form of a slot or a slit, such as located at the lower end of the electrodes. Desirably, the opening extends a length of the first electrode and the second electrode, such as to form a gap between them. Some smaller pieces of solid feedstock may pass through the opening. In the alternative, a screen or sieve device prevents the solid material from passing through the opening.

The term “catch pan” broadly refers to any suitable device for collecting or receiving the molten feedstock from the melting zone. The catch pan may then supply the molten feedstock into a holding apparatus or a solidification apparatus. The catch pan may include additional restive heaters as desired to maintain the molten feedstock and/or supply superheat to increase a temperature of the molten feedstock, such as at least about 5 degrees of superheat, at least about 10 degrees of superheat, and/or the like. The catch pan may include any suitable size and/or shape. The catch pan may include a generally square shape, a generally rectangular shape, and/or the like. Desirably, the catch pan includes sides to maintain and/or direct a volume of the molten feedstock. The catch pan may include any suitable arrangement or configuration of weirs, baffles, flow modifying devices, and/or the like. The flow modifying devices may catch or retain floating and/or sinking impurities or solids, for example.

A crucible broadly includes a vessel of refractory material or the like used for melting and/or calcining a substance at a high degree of heat or temperature. The crucible may include any suitable size and/or shape, such as holding at least about 200 kilograms of silicon, at least about 300 kilograms of silicon, at least about 400 kilograms of silicon, at least about 500 kilograms of silicon, at least abut 750 kilograms of silicon, at least about 1000 kilograms of silicon, and/or the like.

According to one embodiment, the first electrode and the second electrode slope or angle apart from each other to form a generally V-shaped cross section. The angle of the electrodes may include any suitable angle, such as between about 15 degrees and about 170 degrees, between about 45 degrees and about 135 degrees, between about 70 degrees and about 110 degrees, about 90 degrees, and/or the like. The V-shaped cross section may include any suitable orientation, such as generally vertical, about 30 degrees left, about 60 degrees left, about 30 degrees right, about 60 degrees right, and/or the like.

Desirably, but not necessarily, the melting zone includes a width that increases with a height of the first electrode or the second electrode. In the alternative, the electrodes can be in a generally parallel arrangement while being arranged at any suitable angle, such as generally horizontal, generally vertical, and/or tilted.

According to one embodiment, the melting zone may include a generally trapezoidal shape, such as narrower on the bottom and wider on the top. Other shapes or configurations of the melting zone are within the scope of this invention.

The melting zone may be bounded by the first electrode, the second electrode, and end walls or structures, such as to form a four-sided vessel or device. In the alternative, the melting zone may be exposed on the sides with an open ended trough shape. The end walls may form insulating walls disposed at the end of and between the first electrode and the second electrode. The insulating walls may include any suitable material, such as silica, a high temperature electrically insulating ceramic or refractory, and/or the like.

The opening on the bottom of the melting zone may include an insulating material with at least one aperture or hole, such as disposed within the opening. The insulating material with the aperture may hold or support the solid feedstock before melting or during startup. The insulating material may be in a strip form with a series of holes along the length.

In the alternative, the opening may include a silicon plug, such as disposed at least partially blocking or closing the opening. The silicon plug may be in position during startup and be melted during operation to let silicon flow, for example. The silicon plug may be in place during startup and then physically removed or pulled out of the opening, for example.

According to one embodiment, the first electrode or the second electrode may include a motive force device to displace or move at least a portion of the first electrode or the second electrode. The motive force device may break up or dislocate blocking or bridging feedstock, such as with a continuous or intermittent reciprocating motion. The motive force device may include one or more of a vibrator, a shaker, an actuated cylinder, a servomotor, any other suitable mechanical device, and/or the like.

According to one embodiment, the melting apparatus may include a chute disposed or located above the melting zone, such as for directing solid feedstock into the melting zone. The term “chute” broadly refers to an inclined plane, a sloping channel, or a passage down or through which things may pass or fall. The chute may include any suitable size, angle, and/or shape. Desirably, the chute utilizes gravity or the mass of the solid feedstock to move additional material.

The chute may include additional heaters disposed or located within, such as for preheating or warming the solid feedstock. The additional heaters may include resistive heaters or inductive heaters, as discussed above. Desirably, the additional heaters warm the solid feedstock to at least above ambient conditions, at least about 100 degrees Celsius, at least about 500 degrees Celsius, at least about 1000 degrees Celsius, at least about 1200 degrees Celsius, at least about 1400 degrees Celsius, and/or the like.

According to one embodiment, this invention may include an atmosphere-controlled load lock disposed with respect to the chute or the melting apparatus. The atmosphere-control may be from an inert gas, such as one or more of argon, helium, nitrogen, xenon, and/or the like. In the alternative, the atmosphere-control may include a vacuum or reduced pressure. The load lock may include a series of doors and/or chambers, such as for passing material into the melting device.

The apparatus of this invention may include any suitable voltage supplied to the electrodes, such as between about 100 volts and about 1,000,000 volts, between about 500 volts and about 100,000 volts, between about 1,000 volts and about 10,000 volts, about 4,000 volts, and/or the like. The apparatus of this invention may include any suitable amperage (current flow) supplied to the electrodes, such as between about 10 amps and about 10,000 amps, between about 50 amps and about 2,500 amps, about 1,000 amps, and/or the like. The apparatus of this invention may include any suitable power output supplied to the electrodes, such as between about 1 kilowatt and about 1,000 kilowatts, between about 10 kilowatts and about 100 kilowatts, about 50 kilowatts, and/or the like.

The apparatus of this invention may include any suitable power supply to the electrodes, such as direct current, alternating current, and/or the like. The alternating current may include any suitable frequency or cycles, such as between about 10 hertz and about 440 hertz, between about 40 hertz and about 100 hertz, about 60 hertz, and/or the like. Changing the electrical characteristics (amperage, voltage, cycles, and/or the like) may affect the throughput or capacity of the direct electric melting apparatus.

The electrical current used in this invention may be supplied on a continuous and/or an intermittent basis (on and off). The intermittent basis may allow settling or moving of the feedstock and new or different current paths formed in or through the feedstock upon reintroduction of current. Pulsing or modulating the current may accelerate the melting process.

The apparatus of this invention may include any suitable life cycle, such as between about 10 hours and about 10,000 hours of operation before replacement of the electrodes, between about 500 hours and about 2,000 hours of operation before replacement of the electrodes, and/or the like of operation before replacement of the heater element.

The bottom of the electrodes near the opening may include an electrically insulating material or shield, such as to prevent electrical arcing or short circuiting of the current. The shield can prevent current from bypassing the solid feedstock.

The direct electric melting apparatus of this invention may further include one or more supplemental heaters located or disposed with respect to the melting zone. The supplemental heaters may include resistive heaters or inductive heaters, as discussed above. The supplemental heaters may supply sensible heat, heat of fusion, and/or superheat to the feedstock. The supplemental heaters may be located above, below, and/or on the sides of the melting zone or the electrodes. According to one embodiment, the supplemental heaters warm the feedstock through the insulating walls.

The supplemental heaters in combination with the direct electric melting may form a hybrid or combination melting system or melter. The supplemental heaters may be implanted in the support walls, such as to form “hot coils”. Desirably by combining direct electric melting with induction heating and/or radiative heating, the apparatus may include more power and/or a greater efficiency.

As used herein the terms “having”, “comprising”, and “including” are open and inclusive expressions. Alternately, the term “consisting” is a closed and exclusive expression. Should any ambiguity exist in construing any term in the claims or the specification, the intent of the drafter is toward open and inclusive expressions.

Regarding an order, number, sequence and/or limit of repetition for steps in a method or process, the drafter intends no implied order, number, sequence and/or limit of repetition for the steps to the scope of the invention, unless explicitly provided.

According to one embodiment, this invention may include a method of continuously melting a feedstock suitable for producing high purity silicon. The method may include the step of providing a solid feedstock, and the step of supplying the solid feedstock into a melting zone between a first electrode and a second electrode. The method may also include the step of passing an electric current from the first electrode through the solid feedstock to the second electrode to melt the solid feedstock into a molten feedstock, and the step of flowing the molten feedstock through an opening between the first electrode and the second electrode optionally into a catch pan or a crucible for receiving the molten feedstock.

The term “providing” broadly refers to supplying and/or preparing in advance. The step of providing a feedstock may include placing and/or loading for use material into a load lock, a chute, a melting zone, and/or the like. Optionally, providing may include preheating to a suitable temperature.

The term “solid feedstock” broadly refers to a material or a substance generally not in the liquid state or the gaseous state, such as may include a definite volume and a definite shape. According to one embodiment, the solid feedstock includes high purity silicon.

The term “supplying” broadly refers to providing for or making available for use.

The term “between” broadly refers to in the space that separates, such as a surface of the two electrodes. The first electrode may include a positive charge and the second electrode may include a negative charge or the opposite charges may apply. Desirably, solid feedstock between the electrodes forms or bridges an electric circuit.

The term “passing” broadly refers flowing or moving in a path or circuit, such as from the first electrode through the solid feedstock and into the second electrode. The passing of the electric current may melt the solid feedstock with Joule heating, as described above.

The term “flowing” broadly refers to moving or circulating, such as liquid or molten feedstock. Desirably, but not necessarily, the flowing may include molten feedstock passing between or through a tapered cross section formed by the first electrode and the second electrode. The melted feedstock may dwell or reside within the melting zone for any suitable amount of time, such as a residence time of less than about 60 seconds, less than about 30 seconds, less than about 10 seconds, less than about 5 seconds, less than about 1 second, less than about 0.5 seconds, less than about 0.1 seconds, and/or the like.

According to one embodiment, the method may include the step of bridging between the first electrode and the second electrode with the solid feedstock, such as to form a conductive path or circuit for the electric current. The method may also include the step of placing a silicon plug in the opening before the passing of the electric current, such as to aid or assist in startup of the melting apparatus.

The method may also include the step of loading solid feedstock between the first electrode and the second electrode before the passing of the electric current, such as to aid or assist in startup or continuous operation of the melting apparatus. According to one embodiment, the method may include the step of containing the solid feedstock and/or the molten feedstock between the first electrode and the second electrode with an insulating wall, a barrier, and/or any other suitable structure.

Desirably, but not necessarily, the method of melting may exclude refining or substantial purification of the feedstock, such as reducing an impurity level. Also desirably, the impurity level of the feedstock does not significantly increase during melting. According to one embodiment, the impurity level of the feedstock remains the same or substantially the same before and after melting.

The method may also include the step of actuating or reciprocating a motive force device to displace at least a portion of the first electrode and/or the second electrode, such as to break or displace bridging or built-up blockage of the solid feedstock. The actuating may include any suitable distance and/or frequency. The distance may include at least about 0.1 centimeters, at least about 1 centimeter, at least about 2 centimeters, and/or the like. The frequency may include at least about 1 per minute, at least about 10 per minute, at least about 1 per second, at least about 10 per second, and/or the like.

Desirably, the solid feedstock may include ambient material without preheating to above ambient conditions. In the alternative, the solid feedstock may be preheated to above ambient conditions, as discussed above.

According to one embodiment, the step of bridging the solid feedstock between the first electrode and the second electrode includes where as the solid feedstock becomes smaller, maintaining the bridging by letting gravity move or settle the solid feedstock (further) down between the tapered cross section formed by the first electrode and the second electrode. Desirably, a decreasing particle diameter (melting) of solid feedstock falls by gravity deeper into the V-shape, for example.

The method may also include the step of stacking or placing solid feedstock in a chute above the melting zone, and the step of flowing, sliding, and/or falling the solid feedstock down the chute and into the melting zone by a mass (weight) of the solid feedstock as melting proceeds within the melting zone. Stacking additional solid feedstock may allow or provide for replenished solid feedstock and continuous melting, for example.

The method may also include the step of feeding or supplying the solid feedstock through an atmosphere-controlled load lock to the chute or the melting zone, such as under an inert atmosphere. The load lock may operate in sequential evacuating and filling, such as with air or inert gas. The doors of the load lock may be closed and the atmosphere evacuated before air can be supplied into the chamber. The outside door may be opened and additional solid feedstock charged to the chamber before the door can be closed and the air evacuated. Then inert gas can be supplied or flooded in before opening the inside door and allowing the solid feedstock to be used or added to the chute or the melting zone. The load lock process may be repeated and inert gas can be recycled, such as with a rebreather device.

According to one embodiment, the method may include the step of filling or blanketing the chute with inert gas to form a gravity-based inert atmosphere, such as with argon. Desirably, the inert gas may be denser or heavier than air. The chute may insulate the solid feedstock and the method may include the step of preheating the solid feedstock in the chute with radiant heating from the melting zone, such as from the hot liquid surface.

The method may also include the step of preheating the solid feedstock with additional heaters in the chute, such as resistive or inductive heaters. The operation of the melting apparatus may include varying a voltage to or a power output of the additional heaters, such as supplying a high voltage (at least about 30 volts) to the additional heaters during startup, and supplying a lower voltage (less than about 15 volts) to the additional heaters during continuous melting. The preheating may be used during startup, such as to allow or permit the electrodes to operate at low voltages.

It will be apparent to those skilled in the art that various modifications and variations can be made in the disclosed structures and methods without departing from the scope or spirit of the invention. Particularly, descriptions of any one embodiment can be freely combined with descriptions or other embodiments to result in combinations and/or variations of two or more elements or limitations. Other embodiments of the invention will be apparent to those skilled in the art from consideration of the specification and practice of the invention disclosed herein. It is intended that the specification and examples be considered exemplary only, with a true scope and spirit of the invention being indicated by the following claims.

What is claimed is:

1. A continuous melting apparatus suitable for producing high purity silicon, the apparatus comprising:
a first electrode opposite a second electrode and forming a melting zone for an electric current to pass from the first electrode through a feedstock and enter the second electrode;
an opening for draining a molten feedstock from the melting zone; and
optionally a catch pan or a crucible for receiving the molten feedstock from the opening.

2. The apparatus of claim 1, wherein the first electrode and the second electrode slope apart from each other to form a generally V-shaped cross section.

3. The apparatus of claim 1, wherein the melting zone has a width that increases with a height of the first electrode or the second electrode.

4. The apparatus of claim 1, wherein the melting zone has a generally trapezoidal shape.

5. The apparatus of claim 1, further comprising an insulating material with at least one aperture disposed within the opening.

6. The apparatus of claim 1, wherein the first electrode and the second electrode comprise graphite, silicon carbide, or coated carbon-carbon composite material.

7. The apparatus of claim 1, further comprising insulating walls disposed at the end of and between the first electrode and the second electrode.

8. The apparatus of claim 1, wherein the insulating walls comprise silica.

9. The apparatus of claim 1, wherein the first electrode or the second electrode comprise a motive force device to displace at least a portion of the first electrode or the second electrode.

10. The apparatus of claim 1, further comprising a silicon plug disposed in the opening.

11. The apparatus of claim 1, further comprising a chute disposed above the melting zone.

12. The apparatus of claim 11, further comprising an atmosphere-controlled load lock disposed with respect to the chute.

13. The apparatus of claim 11, further comprising additional heaters disposed with respect to the chute.

14. A method of continuously melting a feedstock suitable for high purity silicon, the method comprising:
providing a solid feedstock;
supplying the solid feedstock into a melting zone between a first electrode and a second electrode;
passing an electric current from the first electrode through the solid feedstock to the second electrode to melt the solid feedstock into a molten feedstock; and
flowing the molten feedstock through an opening between the first electrode and the second electrode optionally into a catch pan or a crucible for receiving the molten feedstock.

15. The method of claim 14, further comprising bridging between the first electrode and the second electrode with the solid feedstock.

16. The method of claim 14, further comprising placing a silicon plug in the opening before the passing of the electric current.

17. The method of claim 14, further comprising loading solid feedstock between the first electrode and the second electrode before the passing of the electric current.

18. The method of claim 14, further comprising containing the solid feedstock or the molten feedstock between the first electrode and the second electrode with an insulating wall.

19. The method of claim 14, wherein the melting excludes refining or substantial purification.

20. The method of claim 14, further comprising actuating a motive force device to displace at least a portion of the first electrode or the second electrode, breaking bridging or built-up blockage of the solid feedstock.

21. The method of claim 14, wherein the solid feedstock comprises ambient material without preheating to above ambient conditions.

22. The method of claim 14, wherein the flowing comprises molten feedstock passing between a tapered cross section formed by the first electrode and the second electrode.

23. The method of claim 14, wherein a residence time of melted feedstock within the melting zone comprises less than about 10 seconds.

24. The method of claim 14, further comprising bridging the solid feedstock between the first electrode and the second electrode and as the solid feedstock becomes smaller maintaining the bridging by letting gravity move the solid feedstock down between the tapered cross section formed by the first electrode and the second electrode.

25. The method according to claim 14, further comprising:
stacking solid feedstock in a chute above the melting zone; and
flowing solid feedstock down the chute and into the melting zone by a mass of the solid feedstock as melting proceeds.

26. The method of claim 24, further comprising feeding the solid feedstock through an atmosphere-controlled load lock to the chute.

27. The method of claim 24, further comprising filling the chute with inert gas to form a gravity-based inert atmosphere.

28. The method of claim 24, wherein the chute insulates the solid feedstock and comprising preheating the solid feedstock in the chute with radiant heating from the melting zone.

29. The method of claim 24, further comprising preheating the solid feedstock with additional heaters in the chute.

30. The method of claim 14, further comprising varying a voltage to the additional heaters.

31. The method of claim 29, further comprising:
supplying a high voltage to the additional heaters during startup; and
supplying a lower voltage to the additional heaters during continuous melting.

32. The method of claim 29, wherein the preheating with the additional heaters comprises startup while operating the electrodes at low voltages during startup.
